(19) United States
(12) Patent Application Publication
(10) Pub. No.: US 2023/0326628 A1
(43) Pub. Date: Oct. 12, 2023

(54) ISOLATION WRAP WITH CHOKE

(71) Applicant: Berk-Tek LLC, New Holland, PA (US)

(72) Inventor: Paul Michael Good, New Holland, PA (US)

(21) Appl. No.: 17/658,198

(22) Filed: Apr. 6, 2022

(51) Int. Cl. H01B 11/10; H01B 11/08; H05K 9/00

(52) U.S. Cl. CPC H01B 11/10; H01B 11/08; H05K 9/0075

(57) ABSTRACT

A data cable has a cable core having electrical conductors arranged in twisted pairs, an isolation wrap encompassing the cable core, and a jacket encompassing the cable core and the isolation wrap. The isolation wrap includes a magnetic material that attenuates electrical signals that couple to the isolation wrap. Another data cable has electrical conductors arranged in twisted pairs, a pair shielding layer encompassing a twisted pair of the twisted pairs, and a jacket encompassing the twisted pairs and the pair shielding layer. The pair shielding layer includes a magnetic material that attenuates electrical signals that couple to the pair shielding layer.

### TECHNICAL FIELD

The disclosed subject matter relates generally to data cabling, and in particular to electrical isolation of data cable conductors.

### BACKGROUND

Twisted pair data cables, such as Category 6A and/or other Category cables, can contain an internal electrical isolation layer that attenuates alien crosstalk and/or other electrical interference caused by nearby devices or cables. This electrical isolation layer can be implemented as an isolation wrap or foil that is placed around the cable core during manufacturing, e.g., prior to application of a cable jacket. As advances in network technology enable the transfer of increasing quantities of data, it is desirable to further reduce the amount of unwanted signal coupling between cables that utilize isolation foils and/or wraps.

The above-described deficiencies of current data cables are merely intended to provide an overview of some of the problems of current technology and are not intended to be exhaustive. Other problems with the state of the art, and corresponding benefits of some of the various non-limiting embodiments described herein, may become further apparent upon review of the following detailed description.

### SUMMARY

The following presents a simplified summary of the disclosed subject matter in order to provide a basic understanding of some aspects of the various embodiments. This summary is not an extensive overview of the various embodiments. It is intended neither to identify key or critical elements of the various embodiments nor to delineate the scope of the various embodiments. Its sole purpose is to present some concepts of the disclosure in a streamlined form as a prelude to the more detailed description that is presented later.

In an aspect, a data cable as described herein can include a cable core including electrical conductors arranged in twisted pairs. The data cable can further include an isolation wrap encompassing the cable core, where the isolation wrap includes a magnetic material that attenuates electrical signals that couple to the isolation wrap. The data cable can additionally include a jacket encompassing the cable core and the isolation wrap.

In another aspect, a data cable as described herein can include electrical conductors arranged in twisted pairs. The data cable can also include a pair shielding layer encompassing a twisted pair of the twisted pairs, where the pair shielding layer includes a magnetic material that attenuates electrical signals that couple to the pair shielding layer. Additionally, the data cable can include a jacket encompassing the twisted pairs and the pair shielding layer.

In still another aspect, a method as described herein can include carrying data signals through a data cable via twisted pairs of electrical conductors in an interior of the data cable. The method can further include attenuating, by a layer of magnetic material in the interior of the data cable, electrical interference present in the interior of the data cable.

The following description and the annexed drawings set forth in detail certain illustrative aspects of the subject matter. However, these aspects are indicative of but a few of the various ways in which the principles of the subject matter can be employed. Other aspects, advantages, and novel features of the disclosed subject matter will become apparent from the following detailed description when considered in conjunction with the drawings. It will also be appreciated that the detailed description may include additional or alternative embodiments beyond those described in this summary.

### DESCRIPTION OF DRAWINGS

FIG. 1 is a cross-sectional view of a data cable with an isolation wrap including choke material in accordance with various aspects described herein.

FIG. 2 is a diagram depicting an example magnetic coating that can be applied to cable isolation wrap in accordance with various aspects described herein.

FIG. 3 is a diagram depicting respective example spatial configurations for choke material in a cable isolation wrap in accordance with various aspects described herein.

FIG. 4 is a series of diagrams depicting respective example layer configurations for a cable isolation wrap in accordance with various aspects described herein.

FIGS. 5-6 are cross-sectional views of respective data cables with pair shielding that includes choke material in accordance with various aspects described herein.

FIG. 7 is a cross-sectional view of a data cable with choke material incorporated into an isolation wrap and pair shielding in accordance with various aspects described herein.

FIG. 8 is a flow diagram of a method that facilitates reducing electrical interference in a data cable in accordance with various aspects described herein.

FIGS. 9-10 are flow diagrams of respective methods that facilitate construction of a data cable in accordance with various aspects described herein.

### DETAILED DESCRIPTION

Various specific details of the disclosed embodiments are provided in the description below. One skilled in the art will recognize, however, that the techniques described herein can in some cases be practiced without one or more of the specific details, or with other methods, components, materials, etc. In other instances, well-known structures, materials, or operations are not shown or described in detail to avoid obscuring certain aspects.

Various aspects described herein relate to isolation wraps, and other electrical isolation layers, for data cables that utilize choke materials to reduce the magnitude of electrical signals that couple to the isolation wrap. In doing so, data cable performance can be increased by reducing the amount of unwanted signal coupling between nearby cables that use isolation wraps. While various examples herein relate to Category cables, e.g., cables with Category 6A performance or better, it is noted that the aspects described herein can be applied to any suitable type of data cabling and/or other cables or cords. It is further noted that the term “isolation wrap” is used generally herein to refer to any electrical isolation materials, layers, etc., that can be placed in the interior of a cable, including materials applied as a wrap and/or in any other suitable manner, such as via a foil, a tape, or the like. Unless explicitly stated otherwise, the term “isolation wrap” as used in the description and claims is intended to include all such materials and application methods.

With reference now to the drawings, various views of example data cables are provided. It is noted that the drawings represent merely examples of implementations of data cables, and that implementations other than those explicitly shown and described could also be used without departing from the scope of this description or the claimed subject matter. Further, it is noted that the drawings are not drawn to scale, either within a single drawing or between different drawings.

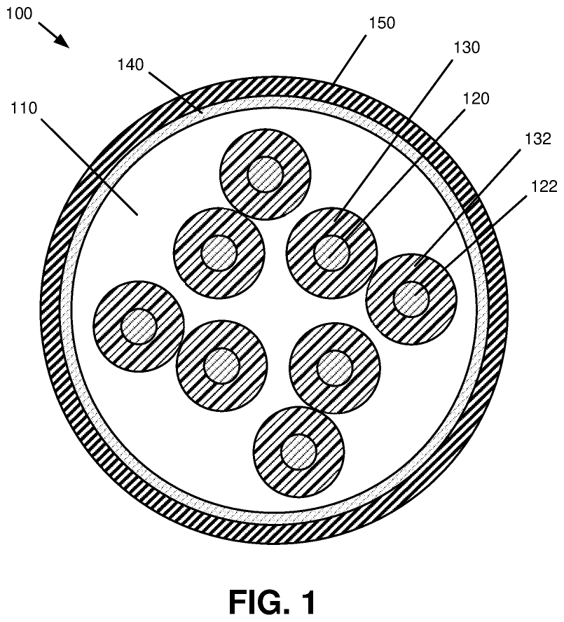

Referring first to FIG. 1, a cross-sectional view of a data cable 100 with an isolation wrap including choke material is presented. As shown by FIG. 1, the data cable 100 includes a cable core 110 in the interior of the data cable 100, e.g., having a shape defined by one or more outer layers of the data cable 100 as described below. The cable core 110 includes electrical conductors 120, 122 that, together, comprise a twisted pair with four twisted pairs of electrical conductors 120, 122 depicted in cable core 110 in FIG. 1. As further shown by FIG. 1, the conductors 120, 122 can be wrapped with and/or otherwise placed in conductor insulators 130, 132, e.g., to prevent direct contact between different conductors 120, 122 and/or between conductors 120, 122 and other elements of the data cable 100, to reduce electrical interference or crosstalk associated with the conductors 120, 122, or for other purposes. For clarity of illustration, only one pair of electrical conductors 120, 122 and corresponding conductor insulators 130, 132 is labeled in FIG. 1.

In an implementation, the conductors 120, 122 can be wires that are composed of copper, tin, and/or other suitable conductive materials. Additionally, the conductors 120, 122 can be composed of the same materials and/or different materials. For example, a first conductor 120 in a given twisted pair can be composed of a first metal, and a second conductor 122 of the pair can be composed of a second, different metal. As further shown in FIG. 1, the conductor insulators 130, 132 associated with a given twisted pair of the data cable can differ in composition and/or appearance. For example, a first conductor insulator 130 of a given twisted pair can be painted and/or otherwise marked, as indicated by line shading in FIG. 1. In other implementations, each twisted pair within the cable core can be given a unique color and/or appearance in order to indicate the proper pairing of the conductors 120, 122. Further, as shown in FIG. 1, a first conductor insulator 130 of a given twisted pair can be comprised of an insulating material comprised of a first composition of materials and a second conductor insulator 132 can be comprised of an insulating material comprised of a second composition of materials that is different than the first composition of materials.

In another implementation, the conductors 120, 122 of each twisted pair can be twisted at a rate, i.e., a rate associated with a given lay length, that is chosen to facilitate optimal electrical performance of the conductors 120, 122 and the data cable 100 as a whole. Additionally, the lay lengths associated with each of the twisted pairs can differ from each other in order to mitigate the effects of electrical resonance and/or other interference caused by adjacent twisted pairs. Other techniques for implementing the twisted pairs are also possible.

While the data cable 100 shown in FIG. 1 includes eight conductors 120, 122 arranged into four twisted pairs, it is noted that a data cable could include any number of conductors or twisted pairs, e.g., from one twisted pair to hundreds of twisted pairs and/or individual conductors, without departing from the scope of this description. Additionally, while the cable core 110 is shown in FIG. 1 as including only the conductors 120, 122, the cable core 110 could also include gels and/or water blocking compounds (e.g., for outside plant cables), cross fillers between the respective conductors or twisted pairs, a central filler element, a rip cord, and/or any other suitable cable components.

As further shown in FIG. 1, the data cable 100 includes an isolation wrap 140 that encompasses and/or otherwise surrounds the cable core 110. In various implementations, the isolation wrap 140 can be placed around the cable core 110 to keep the cable core 110 together during later manufacturing processes, to create space between the cable core 110 and a cable jacket 150, to provide electrical shielding, and/or for other purposes. For instance, the isolation wrap 140 can be used to facilitate attenuation of alien crosstalk and/or other signal leakage from neighboring cables and/or devices.

An isolation wrap 140 as shown in FIG. 1 can be applied in multiple ways. In one example, the isolation wrap 140 can be a continuous element that is helically wrapped and/or folded around the cable core 110. In another example, the isolation wrap 140 can be applied as a discontinuous wrap, e.g., by placing cuts along a layer of aluminum or another suitable material that is applied to the cable core 110. This may be, using one method, accomplished by applying lateral stress to the cut material to stretch the cuts, resulting in gaps being created in the material.

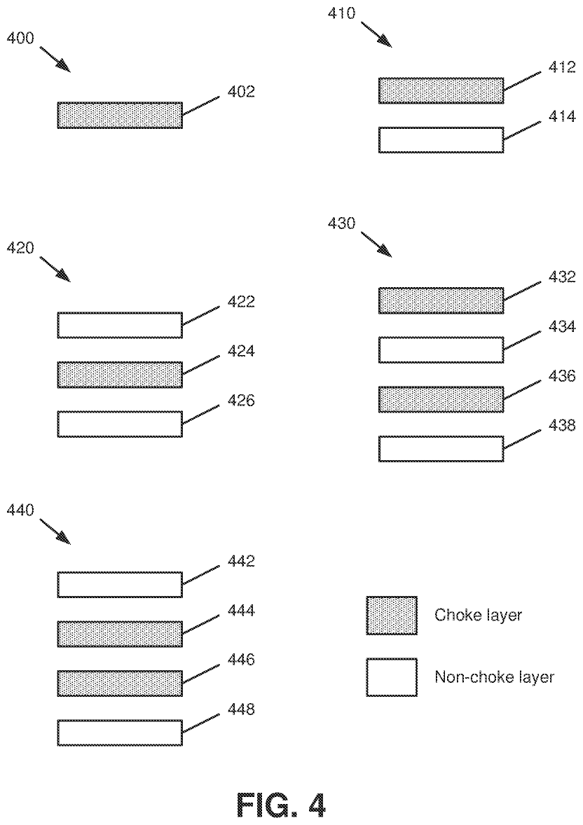

The isolation wrap 140 can be made of non-conductive materials (e.g., polyester, mylar, etc.) and/or conductive materials (e.g., aluminum, copper, etc.). Additionally, while the isolation wrap 140 shown in FIG. 1 is composed of a single layer, it is noted that the isolation wrap 140 could be composed of multiple (e.g., two or more) layers, which could include combinations of different conductive layers, non-conductive layers, or any suitable combination of both conductive and non-conductive layers. By way of example, the isolation wrap 140 can be a trilaminate tape having a conductive layer (e.g., an aluminum layer) between two non-conductive layers (e.g., mylar layers). In another example, the isolation wrap can include an interior layer (e.g., a layer adjacent to the cable core 110) of a non-conductive material and an exterior layer (e.g., a layer adjacent to the cable jacket 150) of a conductive material. Other configurations are also possible. Various compositions that can be utilized by a multi-layer isolation wrap are described in further detail below with respect to FIG. 4.

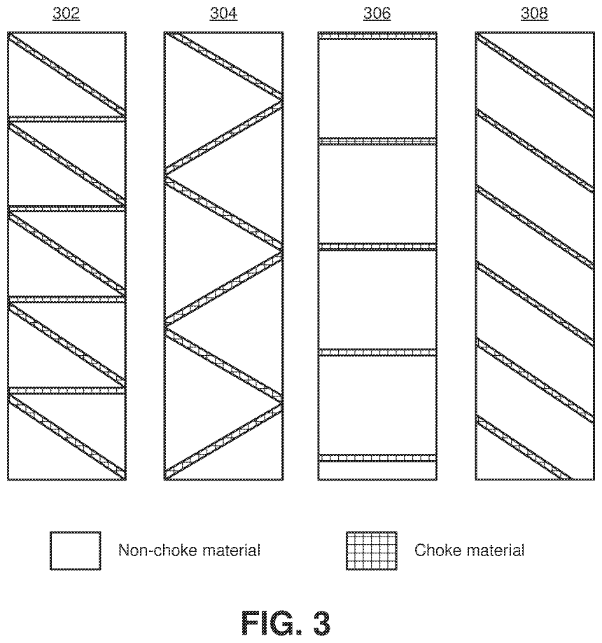

Additionally, individual conductive and/or non-conductive layers of the isolation wrap 140 can be continuous along any axis or broken periodically, either with another material or air. For example, the isolation wrap 140 could include a discontinuous layer of a conductive material (e.g., aluminum) as described above in combination with a continuous layer of another material (e.g., mylar). Examples of break patterns that can be applied to a discontinuous isolation wrap layer are described in further detail below with respect to FIG. 3.

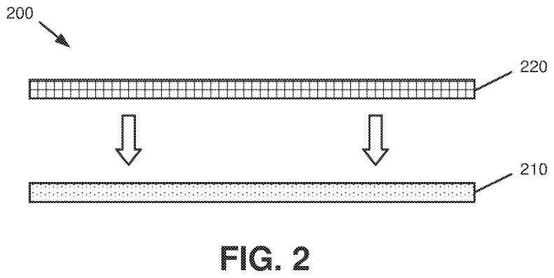

In a typical data cable, an isolation wrap is applied to the entire length of the cable, which can create a continuous or semi-continuous electrical path from one end of the cable to the other. As a result, interference, noise, and/or other unwanted electrical signals that couple to the isolation wrap can travel the whole length of the cable. To attenuate this unwanted signal coupling, the isolation wrap 140 of the data cable 100 shown in FIG. 1 can include a ferrous or magnetic material, e.g., in the form of rings, coatings, or the like that are applied to the isolation wrap 140. This ferrous and/or magnetic material can act as a choke to reduce the magnitude of electrical signals that couple to the isolation wrap 140, e.g., by leveraging hysteresis in the conversion between electrical and magnetic energy in order to attenuate and/or otherwise dissipate unwanted electrical signals traveling through the isolation wrap 140. Various examples of techniques for applying choke materials to an isolation wrap are described in further detail below with respect to FIGS. 2-3.

A choke is an inductive device that can be used for filtering out high frequency signals or noise. An example of a choke is a ferrite core that can be placed around conductors of a cable. In an implementation, the isolation wrap 140 of the data cable 100 can include magnetic (e.g., ferromagnetic, ferrimagnetic, paramagnetic, diamagnetic, antiferromagnetic, etc.) materials in at least one layer in order to form a choke when the isolation wrap 140 is applied around the core 110 of the cable 100. In an example in which the cable 100 is an Ethernet cable, the choke can work to attenuate common mode signals, which is one source of unwanted signal coupling in Ethernet systems.

As further shown in FIG. 1, the data cable 100 can include a jacket 150, e.g., a cable jacket, that houses and/or otherwise encompasses the cable core 110 and the isolation wrap 140. In an implementation, the jacket 150 can be composed of, and/or otherwise include, self-extinguishing and/or otherwise flame resistant materials such as polyvinyl chloride (PVC) and/or fluorinated ethylene propylene (FEP) compounds, low-smoke zero-halogen (LSZH) materials such as ethylene-propylene rubber (EPR) and/or crosslinked propylene (XLPE), and/or other suitable compounds. Other materials could also be used in the construction of the jacket 150. In various implementations, the jacket 150 can be composed of the same material(s) as the conductor insulators 130, 132, and/or other materials could be used.

Turning next to FIG. 2, a diagram 200 depicting an example magnetic coating that can be applied to cable isolation wrap is provided. Repetitive description of like elements employed in other embodiments described herein is omitted for brevity. As shown in diagram 200, an isolation wrap 210, e.g., a non-ferrous, non-magnetic isolation wrap, can be given choke functionality by at least partially applying a coating 220 of choke material to the isolation wrap 210. In an implementation in which the isolation wrap 210 contains more than one layer, the coating 220 can selectively be applied to one or more layers, as will be discussed in further detail below with respect to FIG. 4. In another implementation, the coating 220 can itself act as a separate layer of the isolation wrap 210.

A magnetic material used in a choke layer, e.g., as shown in diagram 200 and/or in other ways as described herein, can contain a continuous or non-continuous coating of material on a substrate composed of any combination of conductive and/or non-conductive materials. In an implementation, the materials providing the choke function can include an oxide compound having one or more metals. By way of specific, non-limiting example, the oxide compound can be of chemical formula ab₂O₄, where a and b represent different metal cations. Also, or alternatively, the oxide compound can be an iron oxide, where at least one metal in the oxide is iron. Other metals that can be used in the choke materials include, but are not limited to, nickel, manganese, zinc, cobalt, strontium, barium, and/or any other suitable metal or combination of metals.

In one implementation as described above, choke materials, such as choke materials associated with the coating 220, can be applied continuously, e.g., to all or substantially all of the surface of the isolation wrap 210. In another implementation, the coating 220 can be applied to the isolation wrap 210 discontinuously, e.g., such that first areas of the isolation wrap 210 are coated with the coating 220 and second, different areas of the isolation wrap 210, are not coated with the coating 220.

With further reference to FIG. 3, various patterns that can be utilized for choke materials on an isolation wrap are shown by diagrams 302, 304, 306, and 308, where the hashed regions indicate areas of the isolation wrap with choke material and the solid regions indicate areas of the isolation wrap with no choke material. It is noted that diagrams 302, 304, 306, 308 are provided merely by way of example and that other patterns are also possible. In an implementation in which the choke material is applied discontinuously according to a pattern, the pattern of application of the choke material can repeat periodically (e.g., over sufficiently long periods) or not repeat at all.

Additionally, each of the diagrams 302, 304, 306, 308 shown in FIG. 3 represent a tape of one or more layers from which an isolation wrap can be formed. In one example, these tapes can be of a thickness of approximately 0.001 to 0.015 inches and a width of approximately 0.250 to 3.100 inches. Other dimensions are also possible. Additionally, while diagrams 302, 304, 306, 308 each represent rectangular tapes, other shapes could also be used.

In addition to coating electrical isolation materials with magnetic material as shown by FIG. 2, other application techniques could also be used. For instance, choke materials could be embedded into one or more conductive and/or non-conductive layers of an isolation wrap, e.g., via doping and/or other techniques. In another example in which a discontinuous isolation wrap is used, choke materials can be placed into respective gaps and/or spaces formed in the isolation wrap. Other techniques could also be used. Further, a concentration of the choke materials used in a given isolation wrap can be selected and/or adjusted as desired to achieve a desired level of signal attenuation.

Turning next to FIG. 4, respective example layer configurations for a cable isolation wrap are illustrated. Repetitive description of like elements employed in other embodiments described herein is omitted for brevity. In the examples shown in FIG. 4, shaded regions represent choke layers of an isolation wrap, i.e., layers in which choke materials are applied, and solid regions represent non-choke layers, i.e., layers in which no choke materials are applied. As first shown by diagram 400, a single-layer tape or wrap can include a layer 402 into which choke materials are coated and/or otherwise embedded, e.g., as described above.

Diagram 410 in FIG. 4 illustrates an example of a two-layer tape that includes a choke layer 412, e.g., a layer that includes magnetic and/or other choke materials, and a non-choke layer 414. While the choke layer 412 is illustrated above the non-choke layer 414 in diagram 410, it is noted that layers 412 and 414 could be reversed, e.g., such that the choke layer 412 is on the other side of the non-choke layer 414.

Diagram 420 illustrates a three-layer tape, e.g., a trilaminate tape, in which a choke layer 424 is positioned between two non-choke layers 422, 426. Similar to the two-layer tape shown in diagram 410, the choke and/or non-choke layers of the tape shown in diagram 420 can be relatively positioned in any suitable manner.

Diagrams 430 and 440 illustrate respective examples of a four-layer tape that can utilize choke materials. With reference first to diagram 430, choke and non-choke layers can be staggered, e.g., such that the choke layers 432, 436 are separated by non-choke layers 434, 438. Alternatively, as shown by diagram 440, a pair of choke layers 444, 446 can be placed adjacent to each other between a pair of non-choke layers 442, 448. While only tapes of up to four layers are shown in FIG. 4, it is noted that an isolation wrap can include any suitable number of layers comprised of choke and/or non-choke materials, which could be configured in a similar manner to the examples shown in FIG. 4.

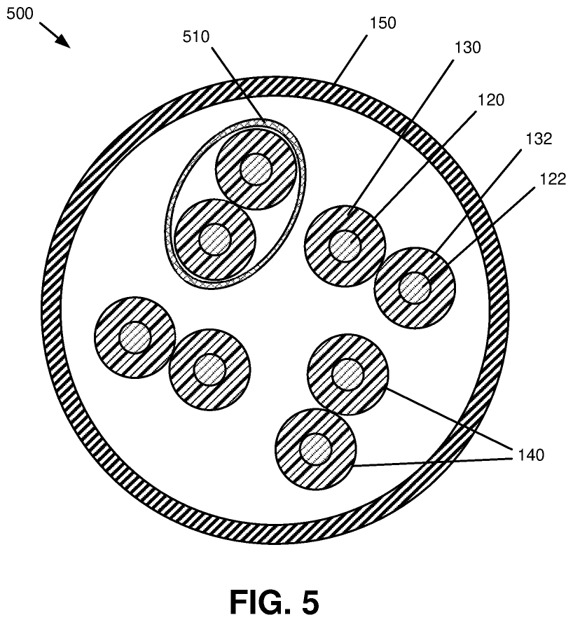

Referring now to FIG. 5, a cross-sectional view of an example data cable 500 with pair shielding that includes choke material is provided. Repetitive description of like elements employed in other embodiments described herein is omitted for brevity. The data cable 500 shown in FIG. 5 includes respective electrical conductors 120, 122, each of which can be enclosed in respective conductor insulators 130, 132 and arranged in twisted pairs in a similar manner to the data cable 100 described above with respect to FIG. 1. Additionally, the data cable 500 can include a cable jacket 150 that is similar to the cable jacket 150 described above with respect to FIG. 1.

As further shown in FIG. 5, a pair shielding layer 510 can encompass and/or otherwise include one or more of the twisted pairs of conductors 120, 122, e.g., by being wrapped, wound, and/or otherwise applied around the twisted pair(s). Similar to the isolation wrap 140 as described above with respect to FIG. 1, the pair shielding layer 510 can include a magnetic (choke) material that attenuates electrical signals that couple to the pair shielding layer 510. For instance, the pair shielding layer 510 can be coated with choke material as described above with respect to FIG. 2 and/or applied in any other suitable manner. Further, the choke material can be continuously applied to the pair shielding layer or discontinuously applied, e.g., according to one or more patterns such as those described above with respect to FIG. 3. Additionally, the pair shielding layer 510 can be applied to the conductors 120, 122 of a twisted pair after the twisting stage.

In some implementations, the pair shielding layer 510 shown in FIG. 5 can be one of multiple pair shielding layers applied to a given twisted pair. For implementations that use multi-layer pair shielding, the pair shielding can include respective choke layers and non-choke layers as described above with respect to FIG. 4. In an example in which two-layer shielding is used, choke materials can be applied to the inner layer of the shielding (with reference to the twisted pair), the outer layer, or both layers.

Choke materials used for the pair shielding layer 510 can be similar to the choke materials described above with respect to the isolation wrap 140. For instance, the pair shielding layer 510 can include an oxide compound, e.g., a compound of the form ab₂O₄ where a and b are different metal cations. Other materials could also be used.

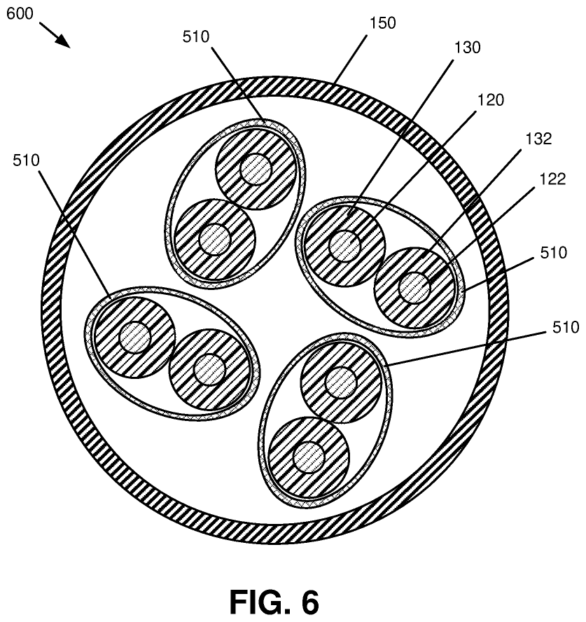

While FIG. 5 illustrates an example in which a pair shielding layer 510 is applied to a single twisted pair of conductors 120, 122, a pair shielding layer could, alternatively, be applied to multiple, or all, twisted pairs. By way of example, FIG. 6 illustrates a data cable 600, that is similar to the data cable 500 described above with respect to FIG. 5, but differs in that pair shielding layers 510 are applied to each twisted pair of the data cable 600. In an implementation such as that shown by FIG. 6 in which pair shielding layers 510 are applied to multiple twisted pairs, the different pair shielding layers 510 can be comprised of the same or different materials, number of layers, and/or other properties.

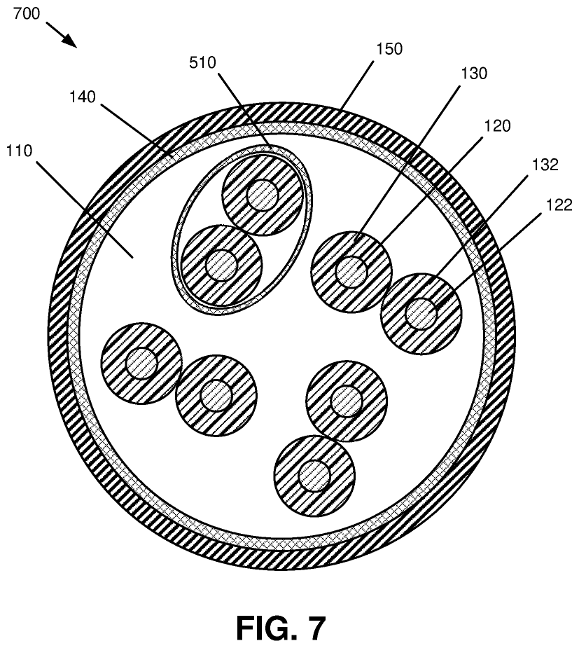

FIG. 7 illustrates another example data cable 700 that includes both an isolation wrap 140, encompassing or enclosing cable core 110, and a pair shielding layer 510 applied to one or more twisted pairs of conductors 120, 122. One or both of the isolation wrap 140 and the pair shielding layer 510 can include choke materials or layers, e.g., as described above with respect to FIGS. 1 and 5. In an implementation in which both the isolation wrap 140 and the pair shielding layer or layers 510 include magnetic and/or other choke materials, the isolation wrap 140 and pair shielding layer or layers 510 could differ in one or more of the choke materials used, the relative positioning of choke materials (e.g., within respective regions as described above with respect to FIG. 3 and/or different layers as described above with respect to FIG. 4), the concentration of choke materials, and/or other properties.

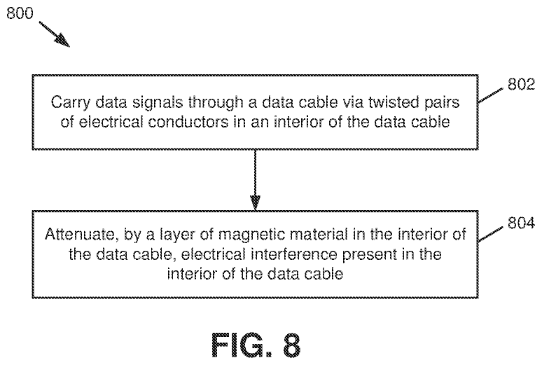

With reference now to FIG. 8, a flow diagram of a method 800 that facilitates reducing electrical interference in a data cable (e.g., a data cable 100) is presented. At 802, data signals are carried through a data cable via twisted pairs of electrical conductors (e.g., conductors 120, 122) in an interior (e.g., a core 110) of the data cable.

At 804, a layer of magnetic material in the interior of the data cable (e.g., a layer of magnetic material associated with an isolation wrap 140 and/or a pair shielding layer 510) attenuates electrical interference present in the interior of the data cable.

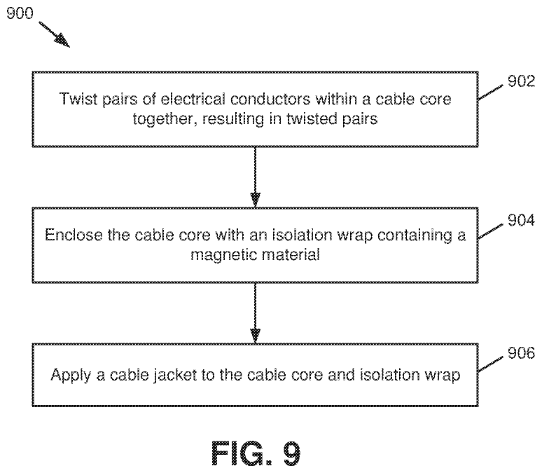

Turning next to FIG. 9, a flow diagram of a first method 900 that facilitates construction of a data cable is presented. At 902, pairs of electrical conductors (e.g., conductors 120, 122) within a cable core (e.g., a cable core 110) are twisted together, resulting in twisted pairs. In an implementation, the twisted pairs can be twisted to the same and/or different lay lengths.

At 904, the cable core is enclosed with an isolation wrap (e.g., an isolation wrap 140) containing a magnetic material. In an implementation, the isolation wrap can be placed at an outer boundary of the cable core, e.g., in a similar manner to data cable 100 as shown in FIG. 1. At 906, construction of the data cable can conclude by applying a cable jacket (e.g., a cable jacket 150) to the cable core and the isolation wrap.

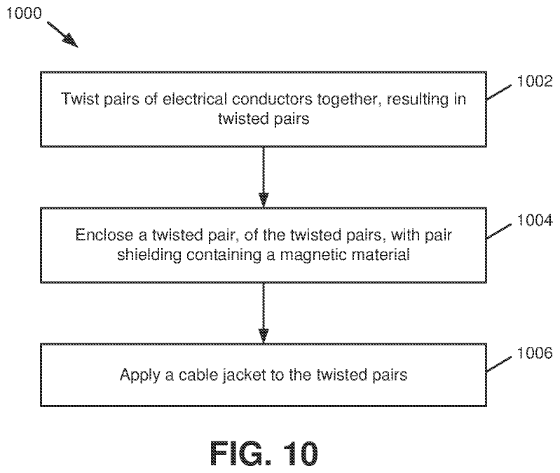

Referring now to FIG. 10, a flow diagram of a second method 1000 that facilitates construction of a data cable is presented. Method 1000 begins at 1002 by twisted pairs of electrical conductors to create twisted pairs, e.g., in a similar manner to that described above at 902 of method 900.

At 1004, a twisted pair of the twisted pairs created at 1002 is enclosed with pair shielding (e.g., a pair shielding layer 510) containing a magnetic material. In some implementations, pair shielding as performed at 1004 can be repeated for some or all of the twisted pairs of the cable. Additionally, an isolation wrap could be applied to the interior of the data cable in a similar manner to that described above at 904 of method 900. At 1006, construction of the data cable can conclude by applying a cable jacket (e.g., a cable jacket 150) to the twisted pairs.

FIGS. 8-10 illustrate methods in accordance with certain aspects of this disclosure. While, for purposes of simplicity of explanation, the methods are shown and described as series of acts, it is noted that this disclosure is not limited by the order of acts, as some acts may occur in different orders and/or concurrently with other acts from that shown and described herein. For example, those skilled in the art will understand and appreciate that methods can alternatively be represented as a series of interrelated states or events, such as in a state diagram. Moreover, not all illustrated acts may be required to implement methods in accordance with certain aspects of this disclosure.

The above description includes non-limiting examples of the various embodiments. It is, of course, not possible to describe every conceivable combination of components or methodologies for purposes of describing the disclosed subject matter, and one skilled in the art may recognize that further combinations and permutations of the various embodiments are possible. The disclosed subject matter is intended to embrace all such alterations, modifications, and variations that fall within the spirit and scope of the appended claims.

With regard to the various functions performed by the above described components, devices, circuits, systems, etc., the terms (including a reference to a “means”) used to describe such components are intended to also include, unless otherwise indicated, any structure(s) which performs the specified function of the described component (e.g., a functional equivalent), even if not structurally equivalent to the disclosed structure. In addition, while a particular feature of the disclosed subject matter may have been disclosed with respect to only one of several implementations, such feature may be combined with one or more other features of the other implementations as may be desired and advantageous for any given or particular application.

The term “or” as used herein is intended to mean an inclusive “or” rather than an exclusive “or.” For example, the phrase “A or B” is intended to include instances of A, B, and both A and B. Additionally, the articles “a” and “an” as used in this application and the appended claims should generally be construed to mean “one or more” unless either otherwise specified or clear from the context to be directed to a singular form.

The terms “first,” “second,” “third,” and so forth, as used in the claims, unless otherwise clear by context, is for clarity only and does not otherwise indicate or imply any order in time. For instance, “a first determination,” “a second determination,” and “a third determination,” does not indicate or imply that the first determination is to be made before the second determination, or vice versa, etc.

The description of illustrated embodiments of the subject disclosure as provided herein, including what is described in the Abstract, is not intended to be exhaustive or to limit the disclosed embodiments to the precise forms disclosed. While specific embodiments and examples are described herein for illustrative purposes, various modifications are possible that are considered within the scope of such embodiments and examples, as one skilled in the art can recognize. In this regard, while the subject matter has been described herein in connection with various embodiments and corresponding drawings, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

1. A data cable, comprising:
a cable core comprising electrical conductors arranged in twisted pairs;
an isolation wrap encompassing the cable core, wherein a surface of the isolation wrap comprises a first area comprising a non-magnetic material and a second area corresponding to a gap formed in the first area, the second area being at least partially filled with a magnetic material that attenuates electrical signals that couple to the isolation wrap; and
a jacket encompassing the cable core and the isolation wrap.

2. The data cable of claim 1, wherein the second area of the surface of the isolation wrap is at least partially coated with the magnetic material.

3. (canceled)

4. The data cable of claim 1, wherein the isolation wrap comprises layers, the layers comprising:
a choke layer comprising the magnetic material; and
a non-choke layer not comprising the magnetic material.

5. The data cable of claim 4, wherein the non-choke layer is a first non-choke layer, wherein the layers further comprise a second non-choke layer not comprising the magnetic material, and wherein the choke layer is positioned between the first non-choke layer and the second non-choke layer.

6. The data cable of claim 1, wherein the magnetic material is an oxide compound comprising a first metal and a second metal that is distinct from the first metal.

7. The data cable of claim 6, wherein the first metal is iron.

8. The data cable of claim 6, wherein the second metal is selected from a group comprising nickel, manganese, zinc, cobalt, strontium, and barium.

9. The data cable of claim 6, wherein the oxide compound is of chemical formula ab₂O₄, where a is the first metal and b is the second metal.

10. A data cable, comprising:
electrical conductors arranged in twisted pairs;
a pair shielding layer encompassing a twisted pair of the twisted pairs, wherein a surface of the pair shielding layer comprises a first area comprising a non-magnetic material and a second area, corresponding to a gap in the first area and being at least partially filled with a magnetic material that attenuates electrical signals that couple to the pair shielding layer; and
a jacket encompassing the twisted pairs and the pair shielding layer.

11. The data cable of claim 10, wherein the magnetic material is a coating surrounding the pair shielding layer, or the pair shielding layer is at least partially coated with the magnetic material.

12. (canceled)

13. The data cable of claim 10, wherein the pair shielding layer is a first pair shielding layer, and wherein the data cable further comprises:
a second pair shielding layer, encompassing the twisted pair and adjacent to the first pair shielding layer, wherein the second pair shielding layer does not comprise the magnetic material.

14. The data cable of claim 10, wherein the magnetic material is an oxide compound comprising a first metal and a second metal that is distinct from the first metal.

15. The data cable of claim 14, wherein the first metal is iron.

16. The data cable of claim 14, wherein the second metal is selected from a group comprising nickel, manganese, zinc, cobalt, strontium, and barium.

17. The data cable of claim 10, further comprising:
a plurality of pair shielding layers, the plurality of pair shielding layers comprising the pair shielding layer, wherein respective ones of the plurality of pair shielding layers encompass respective ones of the twisted pairs.

18. A method, comprising:
carrying data signals though a data cable via twisted pairs of electrical conductors in an interior of the data cable; and
attenuating, by a magnetic material applied to a shielding layer in the interior of the data cable at first areas of the surface of the shielding layer corresponding to gaps formed in second areas of the surface of the shielding layer to which a non-magnetic material is applied, electrical interference present in the interior of the data cable.

19. The method of claim 18, wherein the shielding layer is placed at an outer boundary of the interior of the data cable.

20. The method of claim 18, wherein the shielding layer encompasses a twisted pair of the twisted pairs.

21. The data cable of claim 1, wherein the magnetic material is embedded into the second area of the surface of the isolation wrap via doping.

22. The data cable of claim 1, wherein a concentration of the magnetic material in the second area of the surface of the isolation wrap is selected based on a defined level of signal attenuation to be achieved by the isolation wrap.
